(19) United States
(12) Patent Application Publication
(10) Pub. No.: US 2025/0113738 A1
(43) Pub. Date: Apr. 3, 2025

(54) SEMICONDUCTOR STRUCTURE AND MANUFACTURING METHOD THEREOF

(71) Applicant: ENKRIS SEMICONDUCTOR, INC., Suzhou (CN)

(72) Inventor: Kai CHENG, Suzhou (CN)

(21) Appl. No.: 18/895,135

(22) Filed: Sep. 24, 2024

(30) Foreign Application Priority Data
Sep. 28, 2023 (CN) 202311278743.0

(51) Int. Cl. H10N 30/50; H10N 30/057; H10N 30/082

(52) U.S. Cl. CPC H10N 30/508; H10N 30/057; H10N 30/082

(57) ABSTRACT

According to the present disclosure provided are a semiconductor structure and a manufacturing method thereof, the semiconductor structure includes a base; and a first electrode layer, a first piezoelectric layer, a second piezoelectric layer and a second electrode layer that are sequentially stacked on a side of the base. The second piezoelectric layer is flip bonded to a side of the first piezoelectric layer away from the base, an internal stress of the first piezoelectric layer and an internal stress of the second piezoelectric layer are symmetric, and a longitudinal strain of the first piezoelectric layer and a longitudinal strain of the second piezoelectric layer are symmetric, so that an overall internal stress and an overall longitudinal strain in the semiconductor structure formed by bonding the first piezoelectric layer and the second piezoelectric layer are reduced.

### CROSS REFERENCE TO RELATED APPLICATIONS

This application claims priority to Chinese Patent Application No. 2023112787430 entitled “semiconductor structure and manufacturing method thereof” filed on Sep. 28, 2023, the entire content of which is incorporated herein by reference.

### TECHNICAL FIELD

The present disclosure relates to the field of semiconductor technology, and in particular, to a semiconductor structure and a manufacturing method thereof.

### BACKGROUND

MEMS is the abbreviation of the Micro-Electro-Mechanical System. MEMS devices are capable of converting one form of energy into another form of energy, such as converting electrical energy into mechanical energy or converting mechanical energy into electrical energy. Generally, MEMS devices require a piezoelectric material to achieve different forms of energy conversion. However, the existing piezoelectric materials are easily damaged due to the stress problems caused in the process of manufacturing heterogeneous substrates, and the performance of MEMS devices is not good enough.

### SUMMARY

In order to overcome the problems existing in the related art, according to the present disclosure, a semiconductor structure and a manufacturing method thereof are provided.

According to the first aspect of embodiments of the present disclosure, a semiconductor structure is disclosed, including: a base; and a first electrode layer, a first piezoelectric layer, a second piezoelectric layer, and a second electrode layer that are sequentially stacked on a side of the base;

where, the second piezoelectric layer is flip bonded to a side of the first piezoelectric layer away from the base, an internal stress of the first piezoelectric layer and an internal stress of the second piezoelectric layer are symmetric, and a longitudinal strain of the first piezoelectric layer and a longitudinal strain of the second piezoelectric layer are symmetric, so that an overall internal stress and an overall longitudinal strain in the semiconductor structure formed by bonding the first piezoelectric layer and the second piezoelectric layer are reduced. Optionally, the first piezoelectric layer is a polycrystalline structure, and the second piezoelectric layer is a monocrystalline structure;

or, the first piezoelectric layer is a polycrystalline structure, and the second piezoelectric layer is a polycrystalline structure;

or, the first piezoelectric layer is a monocrystalline structure, and the second piezoelectric layer is a monocrystalline structure;

or, the first piezoelectric layer is a monocrystalline structure, and the second piezoelectric layer is a polycrystalline structure.

Optionally, the second piezoelectric layer is a Group III-nitride material, and a surface of a side of the second piezoelectric layer away from the base is an N surface.

Optionally, the first piezoelectric layer is a Group III-nitride material, and a surface of a side of the first piezoelectric layer close to the base is an N surface.

Optionally, the semiconductor structure further includes:

a first protective layer, between the first piezoelectric layer and the second piezoelectric layer.

Optionally, the first protective layer is made of AlGaN or AlScN.

Optionally, a stress direction applied by the first protective layer to one side of the first piezoelectric layer is the same as a stress direction applied by the base to the other side of the first piezoelectric layer, and a bending momentum direction applied by the first protective layer to the one side of the first piezoelectric layer is opposite to a bending momentum direction applied by the base to the other side of the first piezoelectric layer; and

a stress direction applied by the first protective layer to the second piezoelectric layer is the same as a stress direction applied by the first protective layer to the first piezoelectric layer, and a bending momentum direction applied by the first protective layer to the second piezoelectric layer is opposite to a bending momentum direction applied by the first protective layer to the first piezoelectric layer.

Optionally, the semiconductor structure further includes:

a third electrode layer, between the first piezoelectric layer and the second piezoelectric layer.

Optionally, the semiconductor structure further includes:

a fourth electrode layer, between the first piezoelectric layer and the second piezoelectric layer;

a second protective layer, between the first piezoelectric layer and the fourth electrode layer; and

a third protective layer, between the second piezoelectric layer and the fourth electrode layer.

Optionally, the semiconductor structure further includes: a cavity structure between the first electrode layer and the base, and the cavity structure at least partially penetrates through the base in a thickness direction of the base.

Optionally, the semiconductor structure further includes a through hole, the through hole penetrates through the first electrode layer, the first piezoelectric layer, the second piezoelectric layer, and the second electrode layer, and the through hole is communicated with the cavity structure.

According to another aspect of the present disclosure, a manufacturing method of a semiconductor structure is further disclosed, including:

providing a base;

sequentially forming a first electrode layer and a first piezoelectric layer on a side of the base;

providing a carrier;

preparing a second piezoelectric layer on the carrier;

flip bonding the second piezoelectric layer to a side of the first piezoelectric layer away from the base;

removing the carrier; and

forming a second electrode layer on a side of the second piezoelectric layer away from the base;

where, an internal stress of the first piezoelectric layer and an internal stress of the second piezoelectric layer are symmetric, and a longitudinal strain of the first piezoelectric layer and a longitudinal strain of the second piezoelectric layer are symmetric, so that an overall internal stress and an overall longitudinal strain in the semiconductor structure formed by bonding the first piezoelectric layer and the second piezoelectric layer are reduced.

Optionally, the first piezoelectric layer is a polycrystalline structure, and the second piezoelectric layer is a monocrystalline structure;

or, the first piezoelectric layer is a polycrystalline structure, and the second piezoelectric layer is a polycrystalline structure;

or, the first piezoelectric layer is a monocrystalline structure, and the second piezoelectric layer is a monocrystalline structure;

or, the first piezoelectric layer is a monocrystalline structure, and the second piezoelectric layer is a polycrystalline structure.

Optionally, before bonding the second piezoelectric layer to the side of the first piezoelectric layer away from the base, the method further includes:

forming a first protective layer on the first piezoelectric layer and/or the second piezoelectric layer; and

bonding the second piezoelectric layer to a side of the first piezoelectric layer away from the base includes: bonding the second piezoelectric layer to the side of the first piezoelectric layer away from the base through the first protective layer.

Optionally, a stress direction applied by the first protective layer to one side of the first piezoelectric layer is the same as a stress direction applied by the base to the other side of the first piezoelectric layer, and a bending momentum direction applied by the first protective layer to the one side of the first piezoelectric layer is opposite to a bending momentum direction applied by the base to the other side of the first piezoelectric layer; and

a stress direction applied by the first protective layer to the second piezoelectric layer is the same as a stress direction applied by the first protective layer to the first piezoelectric layer, and a bending momentum direction applied by the first protective layer to the second piezoelectric layer is opposite to a bending momentum direction applied by the first protective layer to the first piezoelectric layer.

Optionally, before bonding the second piezoelectric layer to the side of the first piezoelectric layer away from the base, the method further includes:

forming a third electrode layer on the first piezoelectric layer and/or the second piezoelectric layer; and

flip bonding the second piezoelectric layer to the side of the first piezoelectric layer away from the base includes: bonding the second piezoelectric layer to the side of the first piezoelectric layer away from the base through third electrode layer.

Optionally, before bonding the second piezoelectric layer to the side of the first piezoelectric layer away from the base, the method further includes:

forming a second protective layer on the first piezoelectric layer, and forming a third protective layer on the second piezoelectric layer;

forming a fourth electrode layer on the second protective layer and/or the third protective layer; and

flip bonding the second piezoelectric layer to a side of the first piezoelectric layer away from the base includes: bonding the second piezoelectric layer to the side of the first piezoelectric layer away from the base through the fourth electrode layer.

Optionally, the method further includes:

providing a first electrode, where the first electrode is electrically connected to the first electrode layer; and

providing a second electrode, where the second electrode is electrically connected to the second electrode layer.

Optionally, sequentially forming a first electrode layer and a first piezoelectric layer on the side of the base further includes:

preparing a sacrificial layer on the base, and sequentially forming the first electrode layer and the first piezoelectric layer on the sacrificial layer; and

removing the sacrificial layer to form a cavity structure, where the cavity structure at least partially penetrates through the base in a thickness direction of the base.

Optionally, after forming a second electrode layer on the side of the second piezoelectric layer away from the base, the method further includes:

etching the second electrode layer, the second piezoelectric layer, the first piezoelectric layer, and the first electrode layer to form a through hole, where the through hole is communicated with the cavity structure.

In embodiments of the present disclosure, in the semiconductor structure, the second piezoelectric layer is flip bonded to a side of the first piezoelectric layer away from the base, an internal stress of the first piezoelectric layer and an internal stress of the second piezoelectric layer are symmetric, and a longitudinal strain of the first piezoelectric layer and a longitudinal strain of the second piezoelectric layer are symmetric, so that an overall internal stress and an overall longitudinal strain in the semiconductor structure formed by bonding the first piezoelectric layer and the second piezoelectric layer are reduced.

The stresses on the first piezoelectric layer and the second piezoelectric layer are tensile stresses, the second piezoelectric layer is flip bonded to a side of the first piezoelectric layer away from the base, and then the first piezoelectric layer and the second piezoelectric layer have opposite warpage tendencies, i.e., the longitudinal strains of the first piezoelectric layer and the second piezoelectric layer are symmetric. The first piezoelectric layer and the second piezoelectric layer both have a tendency of a sunken center and raised edges; where, the base applies tensile stresses to a side of the first piezoelectric layer toward the base, such that the center of the first piezoelectric layer has a tendency to be sunken toward the base; and since the second piezoelectric layer is flip bonded to a side of the first piezoelectric layer away from the base, the tensile stress is applied on a side of the second piezoelectric layer away from the base, the center of the second piezoelectric layer has a tendency to be sunken away from the base.

Therefore, after the first piezoelectric layer and the second piezoelectric layer are bonded, the bending momentum of the first piezoelectric layer 130 and the bending momentum of the second piezoelectric layer 140 are opposite with each other, the internal stress effects of the first piezoelectric layer and the second piezoelectric layer may cancel each other out, and the bending momentums of the first piezoelectric layer and the bending momentum of the second piezoelectric layer also cancel each other out, and then the overall internal stress and the overall longitudinal strain of the semiconductor structure formed after the first piezoelectric layer and the second piezoelectric layer are bonded are reduced, so that the semiconductor structure formed after bonding the first piezoelectric layer and the second piezoelectric layer has a relatively flat surface, reducing the average stress of each layer in the semiconductor structure, which may reduce the warpage of the semiconductor structure formed after bonding the first piezoelectric layer and the second piezoelectric layer and improve the device performance.

It should be understood that, the above general descriptions and the below detailed descriptions are merely examples and explanation, and are not intended to limit the present disclosure.

### BRIEF DESCRIPTION OF DRAWINGS

The accompanying drawings, which are incorporated in and constitute a part of the present disclosure, illustrate examples consistent with the present disclosure and, together with the description to explain the principles of the disclosure.

FIG. 1 is a schematic cross-sectional view of a semiconductor structure according to an embodiment of the present disclosure.

FIGS. 2 to 6 are schematic flow diagrams of manufacturing a semiconductor structure according to an embodiment of the present disclosure.

FIGS. 7 to 10 are schematic flow diagrams of manufacturing a semiconductor structure according to an embodiment of the present disclosure.

FIG. 11 is a schematic structure diagram of a semiconductor structure according to an embodiment of the present disclosure.

FIG. 12 is a schematic structure diagram of a semiconductor structure according to an embodiment of the present disclosure.

FIGS. 13 to 14 are schematic structure diagrams of a semiconductor structure according to an embodiment of the present disclosure.

FIG. 15 is a schematic structure diagram of a semiconductor structure according to an embodiment of the present disclosure.

FIG. 16 is a schematic structure diagram of a semiconductor structure according to an embodiment of the present disclosure.

### DESCRIPTION OF THE REFERENCE NUMERALS

110—base; 110a—carrier; 120—first electrode layer; 130—first piezoelectric layer; 140—second piezoelectric layer; 150—second electrode layer; 160—cavity structure; 170—first protective layer; 171—third electrode layer; 172—second protective layer; 173—third protective layer; 174—fourth electrode layer; 181—first electrode; 182—second electrode; 183—third electrode; 190—through hole.

### DETAILED DESCRIPTION

Embodiments will be described in detail here, examples of which are illustrated in the accompanying drawings. When the following description relates to the accompanying drawings, unless specified otherwise, the same numerals in different drawings represent the same or similar elements. Implementations described in the following examples do not represent all implementations consistent with the present disclosure. Rather, they are merely device examples consistent with some aspects of the present disclosure as detailed in the appended claims.

The terms used in this application are merely for the purpose of describing specific embodiments, and are not intended to limit this application. Terms like “a”, “the” and “said” in their singular forms in the present disclosure and the appended claims are also intended to include plurality, unless clearly indicated otherwise in the context. It should also be understood that, the term “and/or” used herein indicates and includes any or all possible combinations of one or more associated listed items.

It is to be understood that, although terms “first,” “second,” “third,” and the like may be used in the present disclosure to describe various information, such information should not be limited to these terms. These terms are only used to distinguish information of the same category with each other. For example, without departing from the scope of the present disclosure, first information may be referred as second information; and similarly, second information may also be referred as first information. Depending on the context, the word “if” as used herein may be interpreted as “when” or “upon” or “in response to determining”.

MEMS is the abbreviation of the Micro-Electro-Mechanical System. The internal structure size of MEMS devices is generally at the micron or nanometer level, and MEMS is an independent intelligent system. MEMS devices are capable of converting one form of energy into another form of energy, such as converting electrical energy into mechanical energy or converting mechanical energy into electrical energy. Generally, MEMS devices require a piezoelectric material to achieve different forms of energy conversion. Taking as an example a transducer that may convert the mechanical energy and electrical energy of sound waves into each other, when an alternating electric field is applied on a piezoelectric material, the piezoelectric material will vibrate based on the frequency of the applied alternating electric field. If the frequency of the applied alternating electric field happens to be the resonant frequency of the MEMS device, the amplitude value will greatly increase, and there are higher energy conversion efficiency at that frequency, and at this time, the MEMS device as transducers has greater emission sensitivity. On the other hand, when the sound waves are transmitted to the piezoelectric material, the vibration and the deformation of the piezoelectric material will be caused. This vibration will cause alternating charge distribution on the electrodes at both ends of the piezoelectric material. When the frequency of the sound wave is at the resonant frequency point of the MEMS device, it has higher energy conversion efficiency at that frequency, and at this time, the MEMS device as a transducer has greater receiving sensitivity.

However, due to the lattice mismatch and the thermal mismatch between the piezoelectric film layer and adjacent film layers of MEMS devices, the internal stresses of the piezoelectric film layer increase with the increase of the thickness of the piezoelectric film layer, and the defect density in the atomic layer of the piezoelectric film layer also increases layer by layer with the increase of thickness. The piezoelectric material is subjected to high stress, which can easily lead to problems such as the warpage and the crack. These problems result in that the reliability of MEMS devices is poor. If the problem of the warpage or the crack is alleviated by reducing the thickness of the piezoelectric material, it will lead to a decrease in the sensitivity of MEMS devices. Therefore, there is an urgent need for a method to alleviate the problem of the excessive stress in the piezoelectric material, which can lead to the warpage, the crack, and other problems.

In order to overcome the problems existing in the related art, the present disclosure provides at least an exemplary embodiment of a semiconductor structure.

### Embodiment 1

FIG. 1 is a schematic cross-sectional view of a semiconductor structure according to Embodiment 1 of the present disclosure. As illustrated in FIG. 1, the semiconductor structure 100 includes: a base 110, and the first electrode layer 120, the first piezoelectric layer 130, the second piezoelectric layer 140, and the second electrode layer 150 that are sequentially stacked on a side of the base 110. The second piezoelectric layer 140 is flip bonded to a side of the first piezoelectric layer 130 away from the base 110. Internal stresses in the first piezoelectric layer 130 and the second piezoelectric layer 140 are symmetric and longitudinal strains in the first piezoelectric layer 130 and the second piezoelectric layer 140 are symmetric, so that the overall internal stress and the overall longitudinal strain of the semiconductor structure formed after bonding the first piezoelectric layer 130 and the second piezoelectric layer 140 are reduced. That the internal stresses in the first piezoelectric layer 130 and the second piezoelectric layer 140 are symmetric refers to that the direction of the internal stress of the first piezoelectric layer 130 is the same as the direction of the internal stress of the second piezoelectric layer 140. That the longitudinal strains in the first piezoelectric layer 130 and the second piezoelectric layer 140 are symmetric refers to that the direction of the longitudinal strain of the first piezoelectric layer 130 is opposite to the direction of the longitudinal strain of the second piezoelectric layer 140.

Optionally, the stress of the first piezoelectric layer 130 and the stress of the second piezoelectric layer 140 are symmetric in direction, the stresses of the first piezoelectric layer 130 and the second piezoelectric layer 140 are tensile stresses, the second piezoelectric layer 140 is flip bonded to a side of the first piezoelectric layer 130 away from the base 110, and then the first piezoelectric layer 130 and the second piezoelectric layer 140 have opposite warpage tendencies, i.e., the longitudinal strains of the first piezoelectric layer 130 and the second piezoelectric layer 140 are symmetric. When the stresses of the first piezoelectric layer 130 and the second piezoelectric layer 140 are tensile stresses, the first piezoelectric layer 130 and the second piezoelectric layer 140 both have a tendency of a sunken center and raised edges; where, the base 110 applies tensile stresses to a side of the first piezoelectric layer 130 close to the base 110, so that the center of the first piezoelectric layer 130 has a tendency to be sunken toward to the base 110; and where, since the second piezoelectric layer 140 is flip bonded to a side of the first piezoelectric layer 130 away from the base 110, a side of the second piezoelectric layer 140 away from the base 110 is subjected to the tensile stress, the center of the second piezoelectric layer 140 has a tendency to protrude at a side away from the base 110. Therefore, the bending momentum of the first piezoelectric layer 130 and the bending momentum of the second piezoelectric layer 140 are opposite with each other, after the first piezoelectric layer 130 and the second piezoelectric layer 140 are bonded, the internal stress effects of the first piezoelectric layer 130 and the second piezoelectric layer 140 may cancel each other out, and the bending momentum of the first piezoelectric layer 130 and the bending momentum of the second piezoelectric layer 140 also cancel each other out, and then the overall internal stress and the overall longitudinal strain of the semiconductor structure formed after bonding the first piezoelectric layer 130 and the second piezoelectric layer 140 are reduced, so that the semiconductor structure formed after bonding the first piezoelectric layer 130 and the second piezoelectric layer 140 has a relatively flat surface, thereby reducing the average stress of each layer in the semiconductor structure, which may alleviate the warpage of the semiconductor structure formed after bonding the first piezoelectric layer and the second piezoelectric layer and improve the device performance.

Optionally, the first piezoelectric layer 130 and the second piezoelectric layer 140 are made of Group III-nitride materials, the surface of a side of the first piezoelectric layer 130 close to the base 110 is a nitrogen (N) surface, for example, the atoms at the entire surface of a side of the first piezoelectric layer 130 close to the base 110 are N atoms, and the surface of a side of the second piezoelectric layer 140 away from the base 110 is a nitrogen (N) surface, for example, the atoms at the entire surface of a side of the second piezoelectric layer 140 away from the base 110 are N atoms. The surface of the side of the second piezoelectric layer 140 away from the base 110 is a nitrogen (N) surface, which can make the semiconductor structure have a flatter surface, and the semiconductor structure having a nitrogen (N) surface is easier to process, thereby reducing the manufacturing difficulties of the subsequent device structures.

The semiconductor structure of this exemplary embodiment can reduce the total internal stress of the first piezoelectric layer 130 and the second piezoelectric layer 140, and alleviate the problem that piezoelectric materials are easily damaged. Furthermore, it alleviates the problem that the piezoelectric material is subjected to high stress, which causes the piezoelectric material to be prone to problems such as prone to warping and cracking.

Referring to FIG. 1, the semiconductor structure provided in the embodiment further includes a first electrode 181 and a second electrode 182, the first electrode 181 is electrically connected to the first electrode layer 120, and the second electrode 182 is electrically connected to the second electrode layer 150.

It should be noted that, the semiconductor structure in the exemplary embodiments of the present disclosure may be used in piezoelectric MEMS devices.

Corresponding to the embodiments of the aforementioned structure, in this embodiment, an exemplary embodiment of a manufacturing method of a semiconductor structure is further provided.

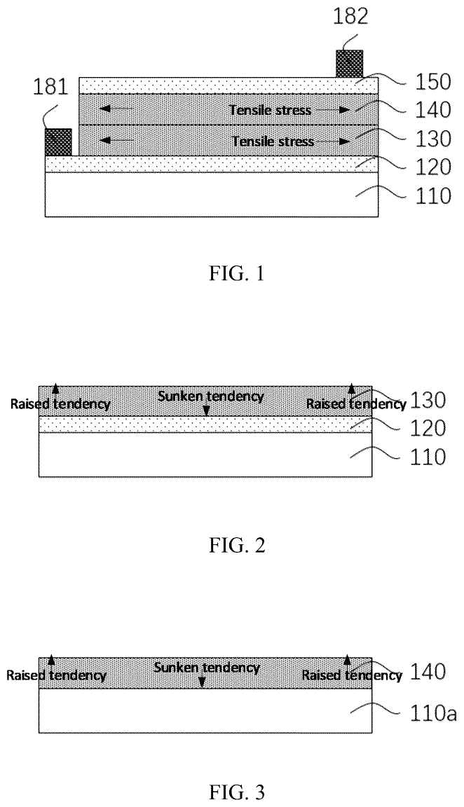

FIGS. 2 to 6 are schematic flow diagrams of manufacturing a semiconductor structure according to an exemplary embodiment of the present disclosure. As illustrated in FIGS. 2 to 6, the manufacturing method of a semiconductor structure 100 includes the following steps.

Step 1: a base 110 is provided, and a first electrode layer 120 and a first piezoelectric layer 130 are sequentially formed on a side of the base 110.

Specifically, as illustrated in FIG. 2, the base 110 may be made of any substrate material such as silicon (Si), monocrystalline lithium niobate (LiNbO₃), silicon carbide (SiC), sapphire (Al₂O₃), quartz (Quartz), etc.

That is, the first electrode layer 120 is between the base 110 and the first piezoelectric layer 130.

The first electrode layer 120 may be made of a conductive material, e.g., a metal, which may specifically be molybdenum, ruthenium, gold, aluminum, magnesium, tungsten, copper, titanium, iridium, osmium, chromium, a composite thereof, or an alloy thereof. The first piezoelectric layer 130 may be made of at least one of lithium niobate (LiNbO₃), lithium tantalate (LiTaO₃), aluminum nitride (AlN), quartz (Quartz), lead zirconate titanate (PZT), lead magnesium niobate-lead titanate (PMN-PT), or aluminum scandium nitride (AlScN), and the first piezoelectric layer 130 may be made of a monocrystalline material or a polycrystalline material. For example, the first electrode layer 120 is made of molybdenum, and the first piezoelectric layer 130 is made of aluminum nitride.

Further, by using the processes such as physical vapor deposition (PVD) or chemical vapor deposition (CVD), the first electrode layer 120 may be formed.

Furthermore, by using physical vapor deposition, chemical vapor deposition, or epitaxial growth process, the first piezoelectric layer 130 may be formed.

Furthermore, the first piezoelectric layer 130 is a polycrystalline structure, or a monocrystalline structure.

For example, a monocrystalline first piezoelectric layer 130 may be formed by using epitaxial growth process, e.g., the first piezoelectric layer 130 may be made of monocrystalline aluminum nitride. The use of epitaxial growth process for the first piezoelectric layer 130 may reduce the defect density, improve piezoelectric characteristics, and thereby enhance the performance (e.g., coupling coefficient and sensitivity, etc.) of MEMS devices including the semiconductor structure.

For example, physical vapor deposition may also be used to form a polycrystalline first piezoelectric layer 130. For example, the first piezoelectric layer 130 is made of polycrystalline aluminum nitride. The use of physical vapor deposition may improve the production efficiency of the semiconductor structures and reduce the production costs.

As a result of the lattice mismatch between the piezoelectric thin film layer 130 and the base 110, the base 110 applies the tensile stress to a side of the first piezoelectric layer 130 close to the base 110, such that the center of the first piezoelectric layer 130 has a tendency to be concave (sunken) toward the base 110.

Step 2: as illustrated in FIG. 3, a carrier 110a is provided, and a second piezoelectric layer 140 is formed on the carrier 110a.

Specifically, the material of the carrier 110a may be made of any substrate material such as silicon (Si), monocrystalline lithium niobate (LiNbO₃), silicon carbide (SiC), sapphire (Al₂O₃), quartz, etc. Optionally, the material of the carrier 110a may be the same as or different from the material of the base 110. Furthermore, to improve the performance of the second piezoelectric layer 140 formed on the carrier 110a, the surface of the carrier 110a is flat and has low roughness, to avoid excessive defects in the second piezoelectric layer 140.

In step 2, the carrier 110a applies the tensile stress to a side of the second piezoelectric layer 140 close the carrier 110a, such that the center of the second piezoelectric layer 140 has a tendency to be concave (sunken) toward the carrier 110a.

In an exemplary embodiment, the first piezoelectric layer 130 is a polycrystalline structure, and the second piezoelectric layer 140 is a monocrystalline structure; or, the first piezoelectric layer 130 is a polycrystalline structure, and the second piezoelectric layer 140 is a polycrystalline structure; or, the first piezoelectric layer 130 is a monocrystalline structure, and the second piezoelectric layer 140 is a monocrystalline structure; or, the first piezoelectric layer 130 is a monocrystalline structure, and the second piezoelectric layer 140 is a polycrystalline structure.

For example, the first piezoelectric layer 130 may be a polycrystalline structure formed by physical vapor deposition, which may improve the production efficiency of the semiconductor structures and reduce the production costs. The second piezoelectric layer 140 may be a monocrystalline structure formed by epitaxial growth, which may improve the sensitivity and the accuracy of the piezoelectric devices including the semiconductor structure. This example may allow for a balance of the efficiency and the sensitivity.

It should be noted that, this embodiment is not intended to limit the material of the first piezoelectric layer 130 and the manufacturing process of the first piezoelectric layer 130, which may be adaptively adjusted according to actual needs.

Optionally, the material of the second piezoelectric layer 140 may be made of at least one of lithium niobate (LiNbO₃), lithium tantalate (LiTaO₃), aluminum nitride (AlN), quartz, lead zirconate titanate (PZT), lead magnesium niobate-lead titanate (PMN-PT), or aluminum scandium nitride (AlScN). Optionally, the material of the second piezoelectric layer 140 may be the same as or different from the material of the first piezoelectric layer 130. For example, the first piezoelectric layer 130 and the second piezoelectric layer 140 are both made of monocrystalline Group III nitride materials (such as monocrystalline aluminum nitride) by epitaxial growth process. Furthermore, the process parameters for epitaxial growth of the first piezoelectric layer 130 and the second piezoelectric layer 140 may be the same. Furthermore, the thickness of the first piezoelectric layer 130 and the thickness of the second piezoelectric layer 140 may be the same or different. The material of the base 110 and the material of the carrier 110a are the same or different.

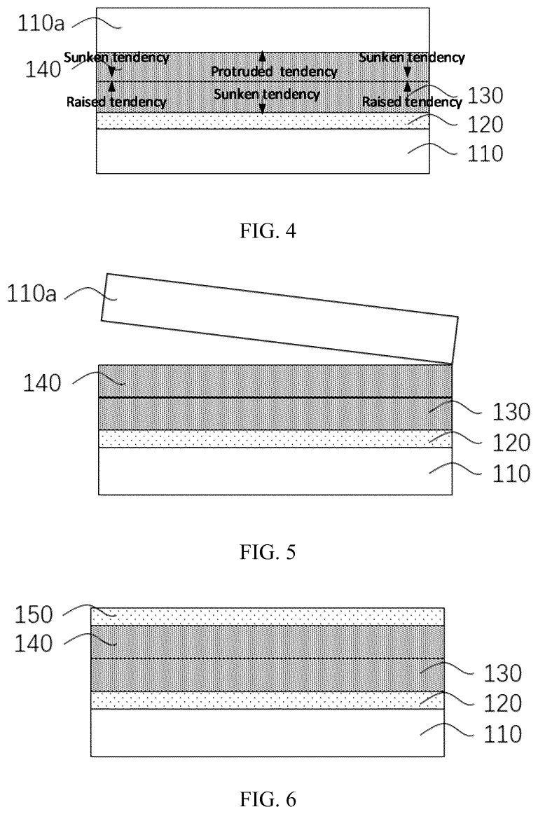

Step 3: referring to FIG. 4, the second piezoelectric layer 140 is flip bonded to a side of the first piezoelectric layer 130 away from the base 110.

Optionally, the second piezoelectric layer 140 is flip bonded to a side of the first piezoelectric layer 130 away from the base 110. Specifically, bonding treatment may be performed on the first piezoelectric layer 130 and the second piezoelectric layer 140 (an exemplary process condition: 425° C., 1500N, holding pressure for 30 minutes).

After that the second piezoelectric layer 140 is flip bonded to the side of the first piezoelectric layer 130 away from the base 110, a side of the second piezoelectric layer 140 away from the base 110 is subjected to a tensile stress, and the center of the second piezoelectric layer 140 has a tendency to protrude at a side away from the base 110. Therefore, the bending momentum of the first piezoelectric layer 130 and the bending momentum of the second piezoelectric layer 140 are opposite with each other, after the first piezoelectric layer 130 and the second piezoelectric layer 140 are bonded, the internal stress effect of the first piezoelectric layer 130 and the internal stress effect of the second piezoelectric layer 140 may cancel each other out, and the bending momentum of the first piezoelectric layer 130 and the bending momentum of the second piezoelectric layer 140 also cancel each other out. Therefore, the semiconductor structure formed after bonding the first piezoelectric layer 130 and the second piezoelectric layer 140 has a relatively flat surface, thereby reducing the average stress of each layer in the semiconductor structure, which may reduce the warpage of the semiconductor structure formed after bonding the first piezoelectric layer 130 and the second piezoelectric layer 140 and improve the device performance.

Step 4: referring to FIG. 5, the carrier 110a is removed.

Optionally, a stripping process is used to remove the carrier 110a.

Step 5: referring to FIG. 6, a second electrode layer 150 is formed on a side of the second piezoelectric layer 140 away from the base 110.

The second electrode layer 150 may be made of a conductive material, e.g., a metal, which may specifically be molybdenum, ruthenium, gold, aluminum, magnesium, tungsten, copper, titanium, iridium, osmium, chromium, a composite thereof, or an alloy thereof. By using physical vapor deposition, or chemical vapor deposition, the second electrode layer 150 may be formed. Optionally, the material of the second electrode layer 150 may be the same as or different from the material of the first electrode layer 120.

Step 6: referring to FIG. 1, a first electrode 181 and a second electrode 182 are further provided. The first electrode 181 is electrically connected to the first electrode layer 120; and the second electrode 182 is electrically connected to the second electrode layer 150. Specifically, a portion of the second electrode layer 150, a portion of the second piezoelectric layer 140, and a portion of the first piezoelectric layer 130 may be etched to expose a portion of the surface of the first electrode layer 120, and the first electrode 181 is formed on the exposed portion of the surface of the first electrode layer 120.

### Embodiment 2

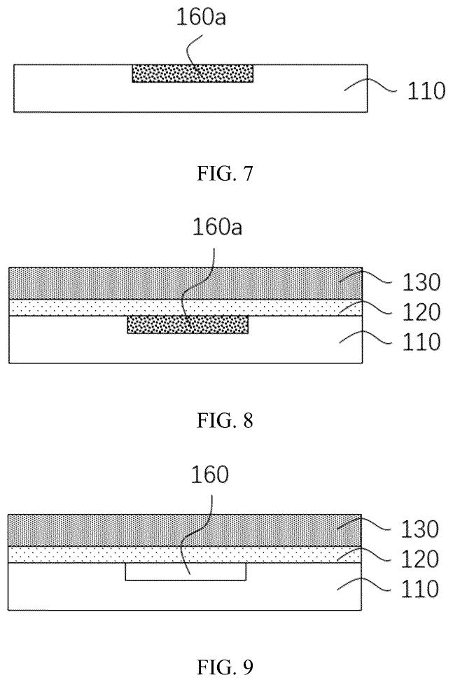

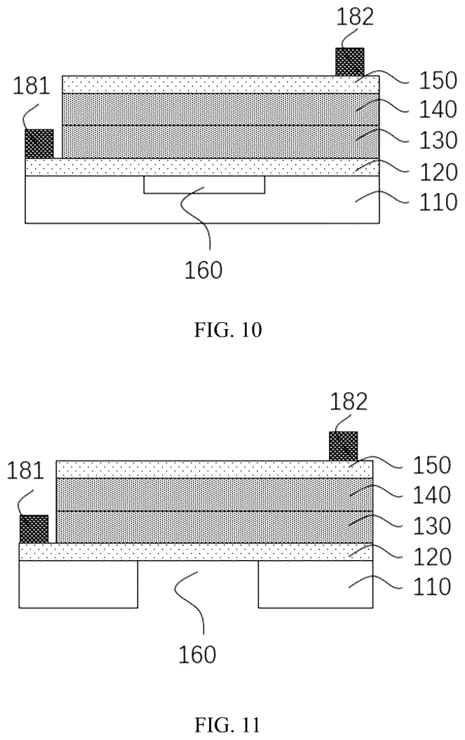

The content of Embodiment 2 is approximately the same as that of Embodiment 1, with the only difference being that, before the first electrode layer 120 and the first piezoelectric layer 130 are sequentially formed on a side of the base 110, a sacrificial layer 160a is formed on the base. Specifically, as illustrated in FIGS. 7 to 10, FIGS. 7 to 10 are schematic flow diagrams of a manufacturing method of the semiconductor structure illustrated in Embodiment 2 of the present disclosure, and FIG. 10 is a schematic diagram of the semiconductor structure illustrated in Embodiment 2 of the present disclosure.

The manufacturing method of the semiconductor structure 200 provided in this embodiment includes the following steps.

Step 11: a base 110 is provided, and a sacrificial layer 160a is formed on the base 110.

As illustrated in FIG. 10, the sacrificial layer 160a may be made of porous silicon, silicon oxide, polysilicon, photoresist, etc. The sacrificial layer 160a may be etched away with a chemical etchant without damaging other film layers. Specifically, a patterned groove may be formed on a side of the base 110 by an etching process, and the sacrificial layer 160a may be formed in the groove; or a partial region of the base 110 may be etched to form the sacrificial layer 160a.

Step 12: referring to FIG. 8, a first electrode layer 120 and a first piezoelectric layer 130 are sequentially formed on a side of the sacrificial layer 160a away from the base 110, and the first electrode layer 120 and the first piezoelectric layer 130 are sequentially formed on the base 110 and the sacrificial layer 160a.

Step 13: referring to FIG. 9, the sacrificial layer 160a is removed. Specifically, the sacrificial layer 160a is removed to form a cavity structure 160 between the first electrode layer 120 and the base. The cavity structure 160 is between the first electrode layer 120 and the base and used to provide a certain space for the piezoelectric material to generate deformation and vibration at the cavity structure 160.

In this embodiment, the sacrificial layer 160a partially or completely penetrates through the base 110, i.e., the cavity structure 160 partially penetrates through the base 110, or the cavity structure 160 completely penetrates through the base 110.

### Embodiment 3

The content of Embodiment 3 is approximately the same as that of Embodiment 1 or Embodiment 2, with the only difference further including that, a cavity structure 160 is formed at the surface of a side of the base 110 away from the first electrode layer 120. The difference from Embodiment 2 mentioned above is that, referring to FIG. 11, which is a schematic structure diagram of a semiconductor structure according to Embodiment 3 of the present disclosure, the cavity structure 160 completely penetrates through the base 110, and may be formed by etching from the side of the base 110 away from the first electrode layer 120.

### Embodiment 4

The content of Embodiment 4 is approximately the same as the content of any one of Embodiment 1 to Embodiment 3, with the only difference further including that, before the second piezoelectric layer 140 is flip bonded to a side of the first piezoelectric layer 130 away from the base 110, a first protective layer 170 is formed on the side of the first piezoelectric layer 130 away from the base 110, and/or a first protective layer 170 is formed on a side of the second piezoelectric layer 140 away from the carrier 110a.

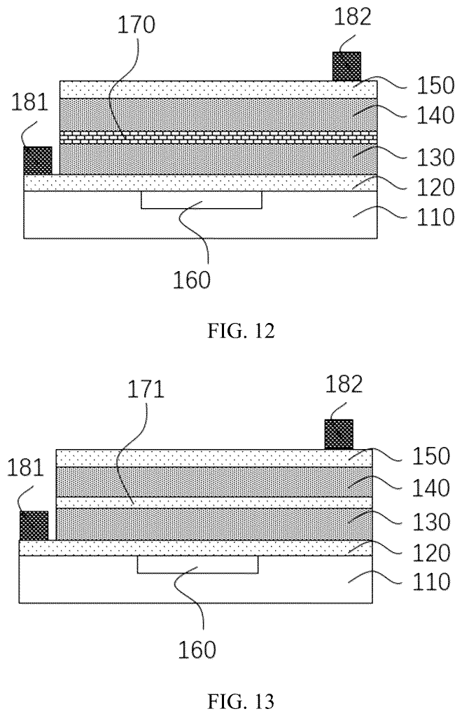

Specifically, referring to FIG. 12, which is a structure diagram of a semiconductor structure according to Embodiment 4 of the present disclosure, before the second piezoelectric layer 140 is flip bonded to a side of the first piezoelectric layer 130 away from the base 110, and after the formation of the first piezoelectric layer 130 and/or the second piezoelectric layer 140, the manufacturing method further includes that, a first protective layer 170 is formed on the first piezoelectric layer 130 and/or the second piezoelectric layer 140, i.e., the first protective layer 170 may be formed only on a side of the first piezoelectric layer 130 away from the base 110, or the first protective layer 170 is formed only on a side of the second piezoelectric layer 140 away from the carrier 110a, or the first protective layer 170 is formed on both of the side of the first piezoelectric layer 130 away from the base 110 and the side of the second piezoelectric layer 140 away from the carrier 110a.

For example, the first protective layer 170 may be made of aluminum gallium nitride (AlGaN), or aluminum scandium nitrogen (AlScN). The first protective layer 170 may be formed by using physical vapor deposition, or chemical vapor deposition.

In this embodiment, the second piezoelectric layer 140 is flip bonded, through the first protective layer 170, to a side of the first piezoelectric layer 130 away from the base 110. The first protective layer 170 is between the first piezoelectric layer 130 and the second piezoelectric layer 140. The stress direction applied by the first protective layer 170 on one side of the first piezoelectric layer 130 is the same as the stress direction applied by the base 110 and/or the first electrode layer 120 on the other side of the first piezoelectric layer 130. Optionally, the base 110 applies the tensile stress to a side of the first piezoelectric layer 130 close to the base 110, such that the center of the first piezoelectric layer 130 has a tendency to be sunken towards the base 110, while the first protective layer 170 applies the tensile stress to a side of the first piezoelectric layer away from the base 110, such that the center of the first piezoelectric layer 130 has a tendency to be sunken at a side away from the base 110, and thus, the bending momentum direction applied by the first protective layer 170 on one side of the first piezoelectric layer 130 is opposite to the bending momentum direction applied by the base 110 on the other side of the first piezoelectric layer 130, and under their interaction, therefore, the first piezoelectric layer 130 can tend to have a relatively flat surface, which improves the problems of the crack, the warpage, the peeling and the like caused by stress difference, lattice mismatch, and thermal mismatch, so as to improve the sensitivity and the performance of the device. Understandably, the stress direction applied by the first protective layer 170 on the second piezoelectric layer 140 is the same as the stress direction applied by the first protective layer 170 on the first piezoelectric layer 130, i.e., the stress direction applied by the first protective layer 170 on the second piezoelectric layer 140 is the same as the stress direction applied by the carrier 110a on the second piezoelectric layer 140, the bending momentum applied by the first protective layer 170 on the first piezoelectric layer 130 is opposite to the bending momentum applied by the first protective layer 170 on the second piezoelectric layer 140, i.e., the bending momentum applied by the first protective layer 170 on the second piezoelectric layer 140 is opposite to the bending momentum applied by the carrier 110a on the second piezoelectric layer 140, such that the second piezoelectric layer 140 can tend to have a relatively flat surface, which improves the problems of the crack, the warpage, the peeling and the like caused by stress difference, lattice mismatch, and thermal mismatch, so as to improve the sensitivity and the performance of the device.

In addition, the first piezoelectric layer 130 and the second piezoelectric layer 140 are bonded through the first protective layer 170, which may improve the bonding strength between the first piezoelectric layer 130 and the second piezoelectric layer 140, and can achieve better bonding effects.

In this embodiment, a first electrode 181 and a second electrode 182 are further provided, the first electrode 181 is electrically connected to the first electrode layer 120; and the second electrode 182 is electrically connected to the second electrode layer 150. The first electrode 181 and the first electrode layer 120 are electrically connected. The second electrode 182 and the second electrode layer 150 are electrically connected.

### Embodiment 5

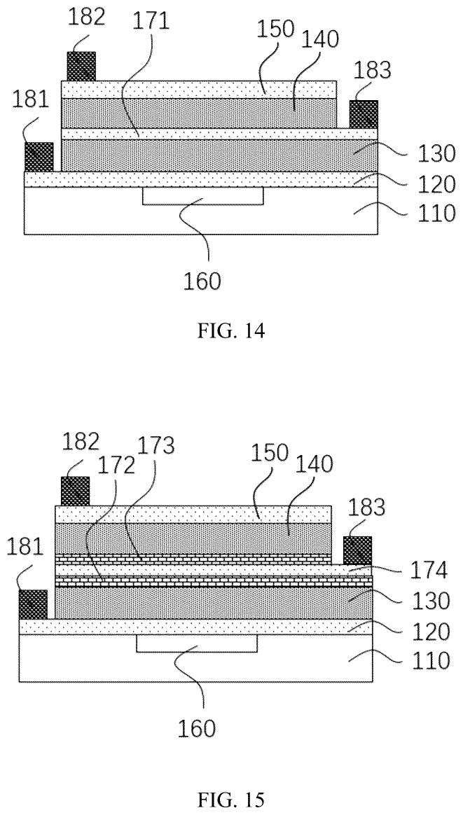

The content of Embodiment 5 is approximately the same as the content of any one of Embodiment 1 to Embodiment 4, with the only difference being as illustrated in FIG. 13 and FIG. 14, which are schematic structure diagrams of a semiconductor structure illustrated in Embodiment 5 of the present disclosure. As illustrated in FIG. 13, in order to further improve the problems of easy cracking or peeling of the piezoelectric film layer, the only difference between the semiconductor structure provided by this exemplary embodiment and the semiconductor structure illustrated in FIG. 12 is that the first protective layer 170 of the semiconductor structure illustrated in FIG. 12 is replaced with a third electrode layer 171. Forming the third electrode layer 171 may specifically be that, the third electrode layer 171 is formed on the first piezoelectric layer 130 and/or the second piezoelectric layer 140. Bonding the second piezoelectric layer 140 to a side of the first piezoelectric layer 130 away from the base 110 includes bonding the second piezoelectric layer 140, through the third electrode layer 171, to a side of the first piezoelectric layer 130 away from the base 110.

The material of the third electrode layer 171 may be referred to the materials of the first electrode layer 120 and the second electrode layer 150. For example, the material of the third electrode layer 171 is the same as the material of the first electrode layer 120. In addition, the sandwich structure composed of the first piezoelectric layer 130, the third electrode layer 171, and the second piezoelectric layer 140 may enhance the coupling ability of the piezoelectric film layers and improve the sensitivity of piezoelectric devices including this semiconductor structure.

Optionally, as illustrated in FIG. 14, the semiconductor structure may further include forming a third electrode 183, which is electrically connected to the third electrode layer 171. The material and process of the third electrode 183 may be referred to the first electrode 181 or the second electrode 182 in the above embodiments, and not be repeated herein again.

### Embodiment 6

The content of Embodiment 6 is approximately the same as that of any one of Embodiment 1 to Embodiment 5, with the only difference being that, after the first electrode layer 120 and the first piezoelectric layer 130 are sequentially formed on the base 110, a second protective layer 172 is formed on a side of the first piezoelectric layer 130 away from the base 110; after the second piezoelectric layer 140 is formed on the carrier 110a, a third protective layer 173 is formed on a side of the second piezoelectric layer 140 away from the carrier 110a; and a fourth electrode layer 174 is formed on a side of the second protective layer 172 away from the first piezoelectric layer 130 and/or on a side of the third protective layer 173 away from the second piezoelectric layer 140. Referring to FIG. 15, FIG. 15 is a schematic structure diagram of a semiconductor structure illustrated in Embodiment 6 of the present disclosure. The manufacturing method of the semiconductor structure provided in this exemplary embodiment includes the following steps.

Step 31: a base 110 is provided, and a first electrode layer 120 and a first piezoelectric layer 130 are sequentially formed on a side of the base 110.

Step 32: a carrier 110a is provided, and a second piezoelectric layer 140 is prepared on the carrier 110a.

Step 33: a second protective layer 172, a third protective layer 173, and a fourth electrode layer 174 are formed. Specifically, referring to FIG. 15, the method includes forming a second protective layer 172 on the first piezoelectric layer 130, forming a third protective layer 173 on the second piezoelectric layer 140, and forming a fourth electrode layer 174 on the second protective layer 172 and/or the third protective layer 173.

For example, the materials of the second protective layer 172 and the third protective layer 173 and the formation processes of the second protective layer 172 and the third protective layer 173 may be referred to the material and the formation process of the first protective layer 170, and not be repeated herein again. The material and the process of the fourth electrode layer 174 may be referred to the material and the process of the third electrode layer 171 in the above embodiments, and not be repeated herein again.

The technical effects of the second protective layer 172 and the third protective layer 173 may be referred to the first protective layer 170, and the technical effect of the fourth electrode layer 174 are referred to the third electrode layer 171, which are not repeated herein again.

Step 34: the second piezoelectric layer 140 is flip bonded to a side of the first piezoelectric layer 130 away from the base 110.

Bonding the second piezoelectric layer 140 to a side of the first piezoelectric layer 130 away from the base 110 includes bonding the second piezoelectric layer 140, through the fourth electrode layer 174, to a side of the first piezoelectric layer 130 away from the base 110.

Specifically, the fourth electrode layer 174 is between the first piezoelectric layer 130 and the second piezoelectric layer 140. The second protective layer 172 is between the first piezoelectric layer 130 and the fourth electrode layer 174. The third protective layer 173 is between the second piezoelectric layer 140 and the fourth electrode layer 174. The second protective layer 172 and the third protective layer 173 provide protection for the piezoelectric layer, alleviating the stress accumulation caused by the increase of the overall thickness of the piezoelectric film layers after bonding the first piezoelectric layer 130 and the second piezoelectric layer 140, thereby alleviating the problems of the crack and the fragmentation of the piezoelectric film layer.

### Embodiment 7

The content of Embodiment 7 is approximately the same as the content of any one of Embodiment 1 to Embodiment 6, with the only difference being that, after the second electrode layer 150 is formed on a side of the second piezoelectric layer 140 away from the carrier 110a, the stacked structure of second electrode layer 150, the second piezoelectric layer 140, the first piezoelectric layer 130, and the first electrode layer 120 are etched to form a through hole 190, and the through hole 190 communicates with the cavity structure 160.

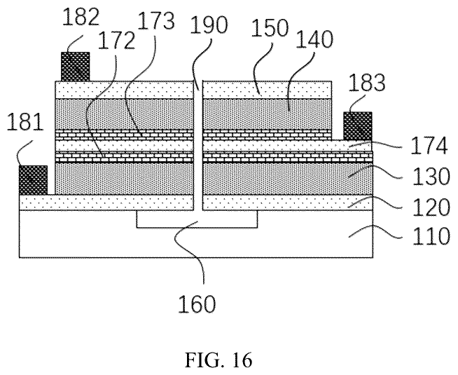

Specifically, referring to FIG. 16, FIG. 16 is a schematic structure diagram of a semiconductor structure provided in Embodiment 7 of the present disclosure. For example, the second electrode layer 150, the second piezoelectric layer 140, the first piezoelectric layer 130, and the first electrode layer 120 are etched to form a through hole 190, and the through hole 190 is communicated with the cavity structure 160. Specifically, the through hole 190 penetrates through the first electrode layer 120, the first piezoelectric layer 130, the second piezoelectric layer 140, and the second electrode layer 150, and is communicated with the cavity structure 160. The through hole 190 is a gap with a relatively small size.

When the deformation of the piezoelectric material is generated, the through hole 190 is used to exhaust the air inside the cavity structure 160 of the piezoelectric material, to reduce the pressure on the piezoelectric material. The communication of the through hole 190 with the cavity structure 160 can improve the sensitivity of the semiconductor structure. The quantity and size of the through holes 190 may be set according to the actual situation, which are not specifically limited here.

The steps not detailed in the exemplary embodiments may be referred to the above exemplary embodiments, which are not repeated herein.

According to the present disclosure, a piezoelectric device is further provided, and the piezoelectric device includes the semiconductor structure provided by any exemplary embodiment mentioned above. Specifically, the piezoelectric device may include a device applied to multiple piezoelectric MEMS devices, for example, the piezoelectric device may be MEMS ultrasonic transducers, MEMS microphones, MEMS speakers, MEMS hydrophones, coupled resonator filters, etc.

The piezoelectric device includes the semiconductor structure provided in any of the above exemplary embodiments and has corresponding beneficial effects, which are not repeated herein.

The embodiments of the present disclosure have been described above. Other implementations are within the scope of the following claims. In some cases, the actions or steps recited in the claims may be performed in a different order than in the embodiments and the desired result may still be achieved. In addition, the processes depicted in the drawings may not require the particular order shown or sequential order to achieve the desired results. In some embodiments, multitasking and parallel processing are also possible or may be advantageous.

Those skilled in the art can easily conceive of other implementations of the present specification after considering the specification and practice of the present disclosure herein. The present disclosure is intended to cover any variations, uses, modification or adaptations of the present disclosure that follow the general principles of the present specification and include common knowledge or conventional technical methods in the related art that are not disclosed in the present disclosure. The specification and implementations are considered as examples only, the true scope and spirit of the present disclosure is indicated by the following claims.

It should be understood that the present disclosure is not limited to the precise structure described above and shown in the accompanying drawings, and various modifications and changes can be made without departing from the scope of the present specification. The scope of the present disclosure is limited only by the appended claims.

The above are the examples of the present disclosure, which are not intended to limit the disclosure. Any modification, equivalent substitution, or improvement made within the spirit and principle of the present disclosure shall be included within the protection scope of the disclosure.

What is claimed is:

1. A semiconductor structure, comprising: a base; and a first electrode layer, a first piezoelectric layer, a second piezoelectric layer, and a second electrode layer that are sequentially stacked on a side of the base;
wherein, the second piezoelectric layer is flip bonded to a side of the first piezoelectric layer away from the base, an internal stress of the first piezoelectric layer and an internal stress of the second piezoelectric layer are symmetric, and a longitudinal strain of the first piezoelectric layer and a longitudinal strain of the second piezoelectric layer are symmetric, so that an overall internal stress and an overall longitudinal strain in the semiconductor structure formed by bonding the first piezoelectric layer and the second piezoelectric layer are reduced.

2. The semiconductor structure according to claim 1, wherein
the first piezoelectric layer is a polycrystalline structure, and the second piezoelectric layer is a monocrystalline structure;
or, the first piezoelectric layer is a polycrystalline structure, and the second piezoelectric layer is a polycrystalline structure;
or, the first piezoelectric layer is a monocrystalline structure, and the second piezoelectric layer is a monocrystalline structure;
or, the first piezoelectric layer is a monocrystalline structure, and the second piezoelectric layer is a polycrystalline structure.

3. The semiconductor structure according to claim 1, wherein the second piezoelectric layer is a Group III-nitride material, and a surface of a side of the second piezoelectric layer away from the base is an N surface.

4. The semiconductor structure according to claim 1, wherein the first piezoelectric layer is a Group III-nitride material, and a surface of a side of the first piezoelectric layer close to the base is an N surface.

5. The semiconductor structure according to claim 1, wherein the semiconductor structure further comprises:
a first protective layer, between the first piezoelectric layer and the second piezoelectric layer.

6. The semiconductor structure according to claim 5, wherein
the first protective layer is made of AlGaN or AlScN.

7. The semiconductor structure according to claim 5, wherein
a stress direction applied by the first protective layer to one side of the first piezoelectric layer is the same as a stress direction applied by the base to the other side of the first piezoelectric layer, and a bending momentum direction applied by the first protective layer to the one side of the first piezoelectric layer is opposite to a bending momentum direction applied by the base to the other side of the first piezoelectric layer; and
a stress direction applied by the first protective layer to the second piezoelectric layer is the same as a stress direction applied by the first protective layer to the first piezoelectric layer, and a bending momentum direction applied by the first protective layer to the second piezoelectric layer is opposite to a bending momentum direction applied by the first protective layer to the first piezoelectric layer.

8. The semiconductor structure according to claim 1, wherein the semiconductor structure further comprises:
a third electrode layer, between the first piezoelectric layer and the second piezoelectric layer.

9. The semiconductor structure according to claim 1, wherein the semiconductor structure further comprises:
a fourth electrode layer, between the first piezoelectric layer and the second piezoelectric layer;
a second protective layer, between the first piezoelectric layer and the fourth electrode layer;
a third protective layer, between the second piezoelectric layer and the fourth electrode layer.

10. The semiconductor structure according to claim 1, further comprising:
a cavity structure, between the first electrode layer and the base, wherein the cavity structure at least partially penetrates through the base in a thickness direction of the base.

11. The semiconductor structure according to claim 10, further comprising:
a through hole, the through hole penetrates through the first electrode layer, the first piezoelectric layer, the second piezoelectric layer, and the second electrode layer, wherein the through hole is communicated with the cavity structure.

12. A manufacturing method of a semiconductor structure, comprising:
providing a base;
sequentially forming a first electrode layer and a first piezoelectric layer on a side of the base;
providing a carrier;
preparing a second piezoelectric layer on the carrier;
flip bonding the second piezoelectric layer to a side of the first piezoelectric layer away from the base;
removing the carrier; and
forming a second electrode layer on a side of the second piezoelectric layer away from the base;
wherein, an internal stress of the first piezoelectric layer and an internal stress of the second piezoelectric layer are symmetric, and a longitudinal strain of the first piezoelectric layer and a longitudinal strain of the second piezoelectric layer are symmetric, so that an overall internal stress and an overall longitudinal strain in the semiconductor structure formed by bonding the first piezoelectric layer and the second piezoelectric layer are reduced.

13. The manufacturing method according to claim 12, wherein
the first piezoelectric layer is a polycrystalline structure, and the second piezoelectric layer is a monocrystalline structure;
or, the first piezoelectric layer is a polycrystalline structure, and the second piezoelectric layer is a polycrystalline structure;
or, the first piezoelectric layer is a monocrystalline structure, and the second piezoelectric layer is a monocrystalline structure;
or, the first piezoelectric layer is a monocrystalline structure, and the second piezoelectric layer is a polycrystalline structure.

14. The manufacturing method according to claim 12, wherein before bonding the second piezoelectric layer to the side of the first piezoelectric layer away from the base, the method further comprises:
forming a first protective layer on the first piezoelectric layer and/or the second piezoelectric layer; and
bonding the second piezoelectric layer to the side of the first piezoelectric layer away from the base comprises: bonding the second piezoelectric layer to the side of the first piezoelectric layer away from the base through the first protective layer.

15. The manufacturing method according to claim 14, wherein,
a stress direction applied by the first protective layer to one side of the first piezoelectric layer is the same as a stress direction applied by the base to the other side of the first piezoelectric layer, and a bending momentum direction applied by the first protective layer to the one side of the first piezoelectric layer is opposite to a bending momentum direction applied by the base to the other side of the first piezoelectric layer; and
a stress direction applied by the first protective layer to the second piezoelectric layer is the same as a stress direction applied by the first protective layer to the first piezoelectric layer, and a bending momentum direction applied by the first protective layer to the second piezoelectric layer is opposite to a bending momentum direction applied by the first protective layer to the first piezoelectric layer.

16. The manufacturing method according to claim 12, wherein before bonding the second piezoelectric layer to the side of the first piezoelectric layer away from the base, the method further comprises:
forming a third electrode layer on the first piezoelectric layer and/or the second piezoelectric layer; and
flip bonding the second piezoelectric layer to the side of the first piezoelectric layer away from the base comprises: bonding the second piezoelectric layer to the side of the first piezoelectric layer away from the base through the third electrode layer.

17. The manufacturing method according to claim 12, wherein before bonding the second piezoelectric layer to the side of the first piezoelectric layer away from the base, the method further comprises:
forming a second protective layer on the first piezoelectric layer, and forming a third protective layer on the second piezoelectric layer;
forming a fourth electrode layer on the second protective layer and/or the third protective layer; and
flip bonding the second piezoelectric layer to the side of the first piezoelectric layer away from the base comprises: bonding the second piezoelectric layer to the side of the first piezoelectric layer away from the base through the fourth electrode layer.

18. The manufacturing method according to claim 12, further comprising:
providing a first electrode, wherein the first electrode is electrically connected to the first electrode layer; and
providing a second electrode, wherein the second electrode is electrically connected to the second electrode layer.

19. The manufacturing method according to claim 12, wherein sequentially forming a first electrode layer and a first piezoelectric layer on the side of the base further comprises:
preparing a sacrificial layer on the base, and sequentially forming the first electrode layer and the first piezoelectric layer on the sacrificial layer; and
removing the sacrificial layer to form a cavity structure, wherein the cavity structure at least partially penetrates through the base in a thickness direction of the base.

20. The manufacturing method according to claim 19, wherein after forming a second electrode layer on the side of the second piezoelectric layer away from the base, the method further comprises:
etching the second electrode layer, the second piezoelectric layer, the first piezoelectric layer, and the first electrode layer to form a through hole, wherein the through hole is communicated with the cavity structure.
